(19) United States
(12) Patent Application Publication
(10) Pub. No.: US 2026/0276674 A1
(43) Pub. Date: Sep. 17, 2026

(54) MILLIMETER-WAVE VECTOR NETWORK ANALYZER

(71) Applicant: Ohio State Innovation Foundation, Columbus, OH (US)

(72) Inventor: Kubilay SERTEL, Hilliard, OH (US)

(21) Appl. No.: 19/167,613

(22) PCT Filed: Mar. 21, 2024
(86) PCT No.: PCT/US2024/020982

§ 371 Date: Sep. 22, 2025

Related U.S. Application Data
(60) Provisional application No. 63/454,188, filed on Mar. 23, 2023.

(51) Int. Cl. G01R 1/07; G01R 27/32; G01R 31/28; G01S 7/41

(52) U.S. Cl. CPC G01R 1/07; G01R 27/32; G01R 31/2822; G01S 7/41

(57) ABSTRACT

Described and disclosed herein are embodiments of a millimeter-wave (mmW) vector network analyzer (VNA). In one aspect, the mmW VNA comprises a conventional automotive/industrial mmW radar circuit board modified to be connected to one or more devices (i.e., connectorized). The mmW radar circuit board comprises a multi-port board with a plurality of receive (Rx) channels and a plurality transmit (Tx) channels and a mmW radar chip; connectors in place of an on-board antenna, wherein the Rx and Tx channels are connected to the one or more devices; and one or more off-axis parabolic mirrors that are used to transmit signals to, from and/or through a sample using the devices.

### CROSS REFERENCE TO RELATED APPLICATION

This application claims priority to and benefit of U.S. provisional patent application Ser. No. 63/454,188 filed Mar. 23, 2023, which is fully incorporated by reference and made a part hereof.

### BACKGROUND

Millimeter-wave (mmW) radar chips operating over 24 GHz, 60 GHz, and 80 GHz ISM bands have been available in the market from multiple vendors for automotive and industrial sensing applications. Future radars will also operate over 140 GHz and 225 GHz bands, with the possibility of increasing beyond 225 GHz. Typically, these radars are used with transmitter and receiver antennas directly fabricated on the printed circuit board (PCB) (see, for example, FIG. 1) where a comparison of a conventional mmW radar PCB vs a PCB of an embodiment of the present invention is illustrated. The conventional utility is based on multiple-input multiple output (MIMO) radar technology. At the core of the mmW radar chip technology is integrated mmW transmitter and receiver circuits, as well as circuit hardware for digital signal processing (see, e.g., Texas Instruments Automotive Radar Products).

However, these chips are particularly designed to be used as conventional radars that can provide real-time sensing, as such their use as a vector network analyzer (VNA) has not been considered before. VNAs are key testing instruments for RF and mmW circuit and component design. Nevertheless, the cost of VNAs increase exponentially for higher frequencies. In particular, the VNA instrumentation for mmW bands is extremely high.

Therefore, a VNA is desired that overcomes challenges in the art, some of which are described above.

### SUMMARY

Described and disclosed herein are VNAs that utilize conventional frequency-modulated continuous wave (FMCW) radar chips with multiple inputs and multiple outputs (MIMO) developed for automotive and industrial sensing applications.

Disclosed and described herein is a VNA comprising a connectorized version of a conventional radar printed circuit board. Performance of the disclosed embodiments of a mmW VNA as a sensitive, metrology-grade instrument is demonstrated including the utility of the disclosed mmW VNA for characterizing electrical properties of material in mmW bands, including reflection and transmission-mode imaging as well as permittivity, permeability and loss characteristics. This innovative demonstration of the utility of the radar chip as a VNA results in an extremely-low cost alternative to mmW measurement of scattering parameters of RF devices and circuits.

In one aspect, a millimeter-wave (mmW) vector network analyzer (VNA) is disclosed. One embodiment of the mmW VNA comprises a mmW radar circuit board modified to be connected to one or more devices, wherein the mmW radar circuit board comprises: a plurality of board ports comprising a plurality of receive (Rx) channels and a plurality of (Tx) channels; a mmW radar chip; and a plurality of connectors. The one or more of the plurality of Rx channels and the one or more of the plurality of Tx channels are connected to the one or more devices using the plurality of connectors. The mmW VNA further comprises one or more off-axis parabolic mirrors, wherein the one or more off-axis parabolic mirrors are used to transmit signals to, from and/or through a sample using the devices.

In some instances, the plurality of board ports comprises seven board ports, comprising four Rx channels and three Tx channels.

In some instances, the plurality of connectors replace an on-board antenna on the mmW radar circuit board.

In some instances, leads are used to connect the Rx and Tx channels to the one or more devices. The one or more devices may comprise one or more Tx antenna, and/or one or more Rx antenna, and/or one or more combination Tx/Rx antenna. In some instance, the one or more devices may further comprise one or more circulators. In some other instances, the one or more devices may further comprise one or more external directional couplers. In yet other instances, the one or more devices may further comprise one or more integrated directional couplers.

In some instances of the mmW VNA, a measurement scenario using the mmW VNA is considered with a target that is rotated in an azimuth and/or elevation direction for transmission and reflection imaging as a function of an incidence angle.

In some instances of the mmW VNA, it is used to determine properties of the sample including multi-port, calibrated, S-parameter measurements, antenna characterization (including input impedance and antenna pattern), scattering cross section measurements, material characterization (permittivity and permeability), and imaging.

Other devices, systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The following detailed description will be better understood when read in conjunction with the appended drawings, in which there is shown one or more of the multiple embodiments of the present disclosure. It should be understood, however, that the various embodiments of the present disclosure are not limited to the precise arrangements and instrumentalities shown in the drawings.

FIG. 1 is a comparison of a conventional mmW radar PCB compared to a PCB of an embodiment of the present invention.

FIG. 2 is an illustration of one of the embodiments of a millimeter-wave vector network analyzer (VNA) that can be used in a transmission measurement scenario.

FIG. 3 is an illustration of one of the embodiments of a mmW VNA that can be used in transmission and reflection measurement scenarios.

FIGS. 4A and 4B are illustrations of embodiments of a mmW VNA that can be used in full, 2-port transmission and reflection measurement scenarios.

FIG. 5 is an illustration of one of the embodiments of a mmW VNA that can be used in a single-port (reflectometer) scenario.

FIG. 6 is an illustration of one of the embodiments of a mmW VNA that can be used in a single-port (reflectometer) imaging measurement scenario.

FIG. 7 is an illustration of one of the embodiments of a mmW VNA that can be used in a transmission and reflection imaging scenario.

FIG. 8 is an illustration of one of the embodiments of a mmW VNA that can be used in an angle-dependent transmission and reflection imaging measurement scenario.

FIG. 9 is an illustration of one of the embodiments of a mmW VNA that can be used as a single-port (reflectometer) using an external directional coupler.

FIG. 10 is an illustration of one of the embodiments of a mmW VNA that can be used as a single-port (reflectometer) using an integrated directional coupler.

FIGS. 11A and 11B illustrate typical signals measured by the mmW VNA when a highly-reflective termination is applied to both ports, termed the Reflect Standard. FIG. 11A illustrates raw measured data and FIG. 11B illustrates measured data after calibration.

FIGS. 12A and 12 B illustrate typical signals measured by the mmW VNA when both ports are connected together, termed the Through Standard. FIG. 12A illustrates raw measured data and FIG. 12B illustrates measured data after calibration.

FIGS. 13A and 13B illustrate typical signals measured by the mmW VNA when a material sample (3.085 mm-thick Thermoplastic Elastomer-TPO) is placed between the two VNA ports. FIG. 13A illustrates raw measured data and FIG. 13B illustrates measured data after calibration.

FIGS. 14A and 14B illustrate typical signals measured by the mmW VNA when a material sample (1.875 mm-thick Acrylic) is placed between the two VNA ports. FIG. 14A illustrates raw measured data and FIG. 14B illustrates measured data after calibration.

FIGS. 15A and 15B illustrate the extracted material properties (i.e. dielectric permittivity) of two representative material samples.

### DETAILED DESCRIPTION

Before the present methods and systems are disclosed and described, it is to be understood that the methods and systems are not limited to specific synthetic methods, specific components, or to particular compositions. It is also to be understood that the terminology used herein is for the purpose of describing particular embodiments only and is not intended to be limiting.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of preferred embodiments and the Examples included therein and to the Figures and their previous and following description.

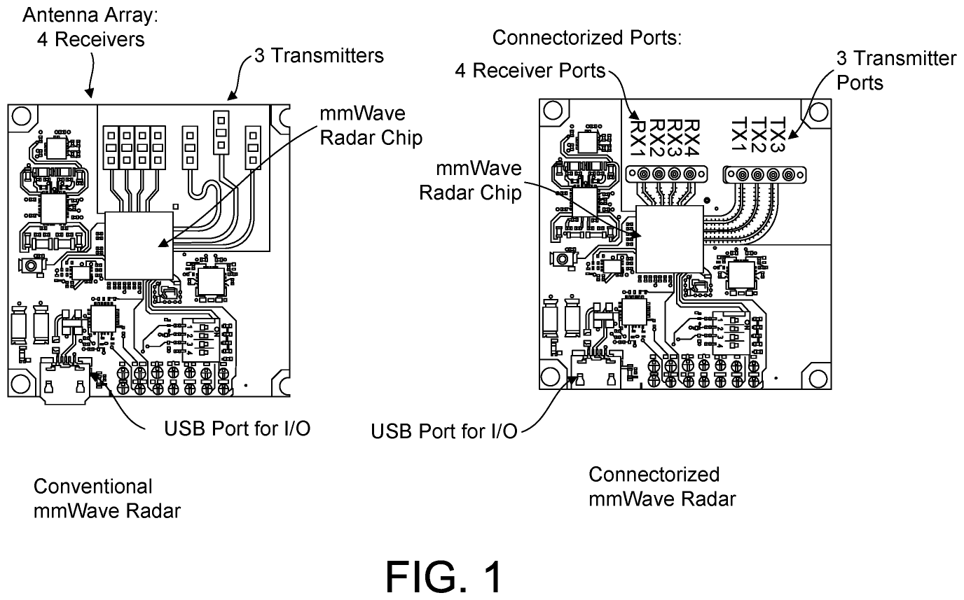

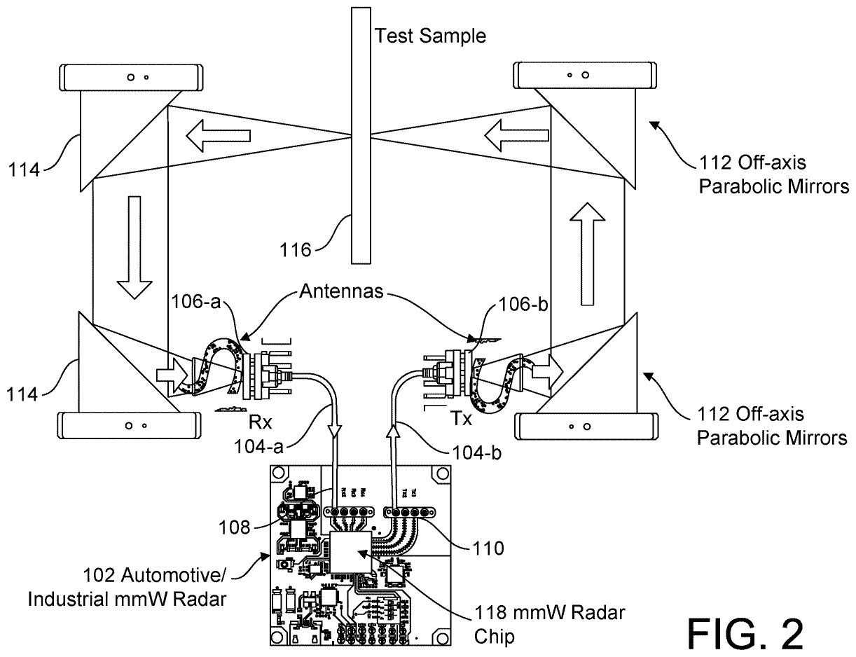

FIG. 2 is an illustration of one of the embodiments of a millimeter-wave vector network analyzer (VNA). This embodiment comprises a conventional automotive/industrial mmW radar circuit board 102 modified to be connected to external leads 104 and devices 106 (i.e., connectorized). The mmW radar circuit board 102 shown in FIG. 1 is a seven-port board with four receive (Rx) channels 108 and three transmit (Tx) channels that includes mmW radar chip 118. Other port, Tx channel and Rx channel numbers and configurations are contemplated within the scope of this disclosure. Rather than having on-board antenna, the mmW radar circuit board 102 now has connectors 108, 110 in place of the on-board antennas. As shown in FIG. 1, leads 104-a and 104-b are used to connect ports 108, 110 to devices 106-a (Rx antenna) and 106-b (transmit antenna) using connectors 108, 110. Further comprising the embodiment of FIG. 1 are off-axis parabolic mirrors 112, 114 that are used to collimate the transmit signals to, from and/or through sample 116, and receive the subsequent signals using a Tx antenna 106-b and a Rx antenna 106-a, connected to the respective ports on the PCB. The received signals can be used to determine properties of the sample 116 including multi-port, calibrated, S-parameter measurements, antenna characterization (including input impedance and antenna pattern), scattering cross section measurements, material characterization (permittivity and permeability), imaging, and the like, providing the full utility of a conventional VNA.

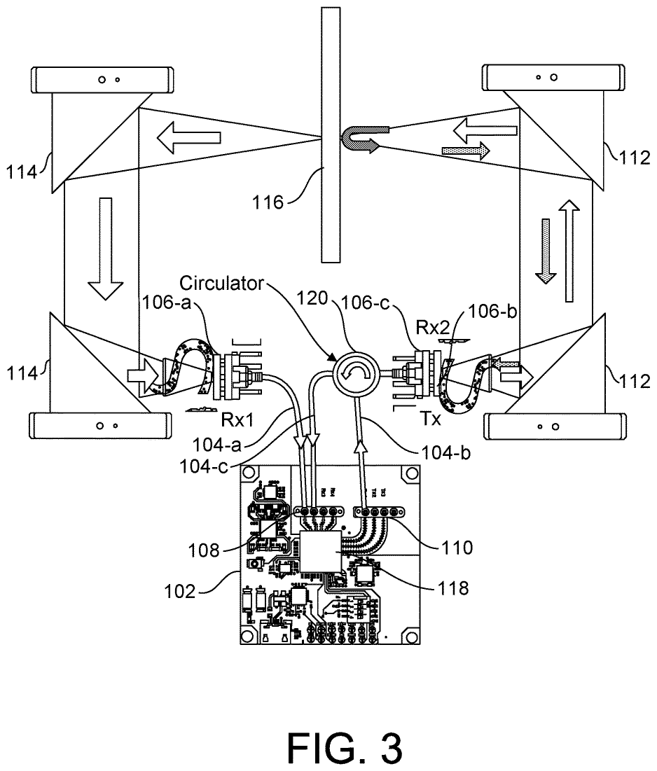

FIG. 3 is an illustration of one of the embodiments of a mmW VNA that can be used in transmission and reflection measurement scenarios. In this scenario, reflections from the sample 116 can be obtained and measured. This is accomplished by a second Rx antenna 106-c (Rx2) and a circulator 120 where reflected signals are gathered by the second Rx antenna 106-c (Rx2) and directed to the Rx port of the mmW radar circuit board 102 using circulator 120, a second Rx lead 104-c, and Rx connector 108.

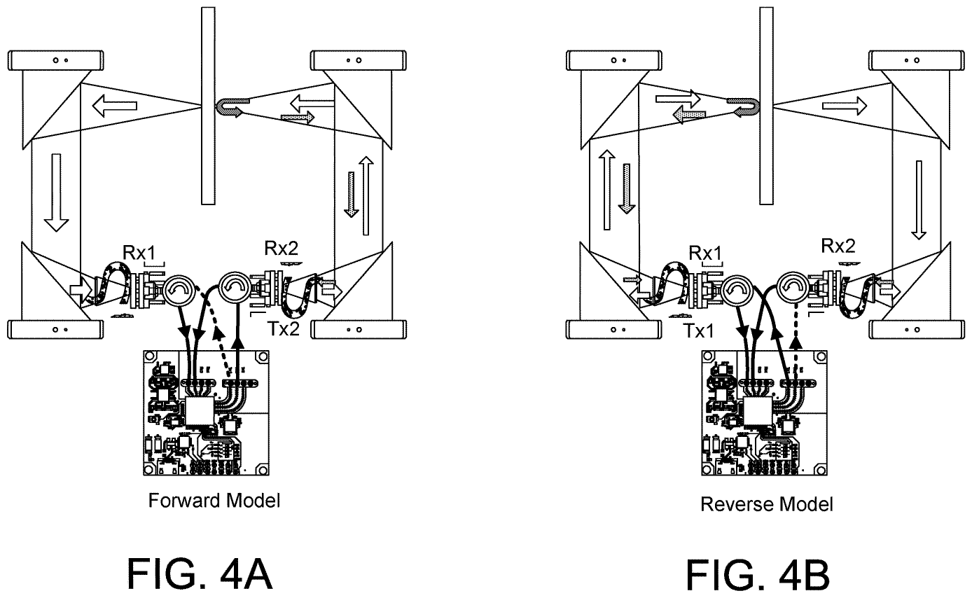

FIGS. 4A and 4B are illustrations of embodiments of a mmW VNA that can be used in full, 2-port transmission and reflection measurement scenarios. FIG. 4A illustrates an embodiment of a mmW VNA comprising two circulators and additional leads connected to the connectors 108, 110, and a Tx antenna on the forward side that can be used to take measurements, including reflections, in the forward direction. FIG. 4B illustrates an embodiment of a mmW VNA comprising two circulators and additional leads connected to the connectors 108, 110, and a Tx antenna on the reverse side that can be used to take measurements, including reflections, in the reverse direction.

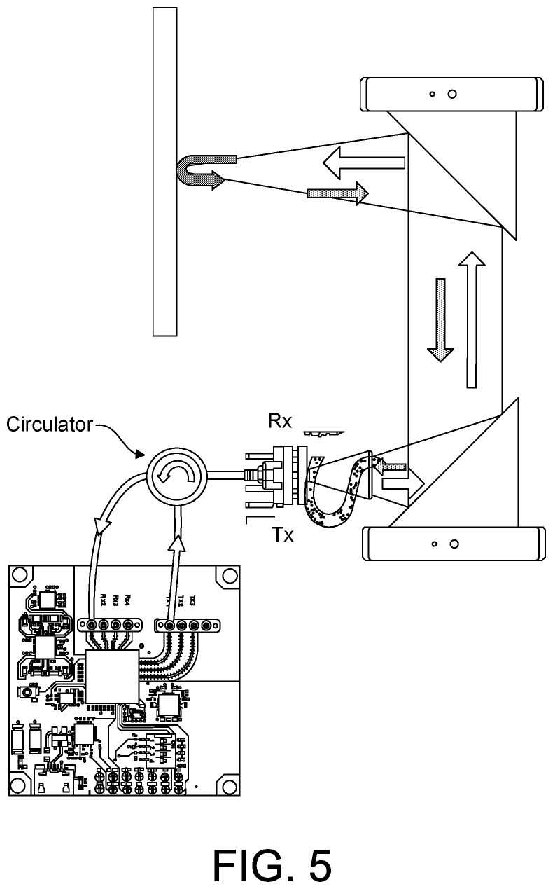

FIG. 5 is an illustration of one of the embodiments of a mmW VNA that can be used in a single-port (reflectometer) scenario. In this scenario, a single Rx/Tx antenna is connected to the Rx and Tx ports of the mmW radar circuit board 102 using a circulator. This scenario obtains reflections from the sample 116.

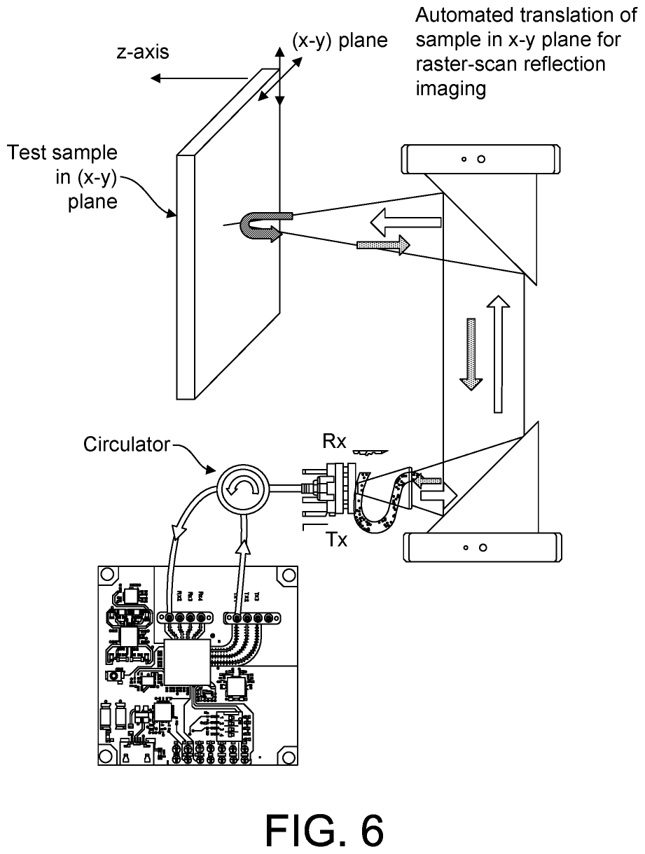

FIG. 6 is an illustration of one of the embodiments of a mmW VNA that can be used in a single-port (reflectometer) imaging measurement scenario. This scenario obtains reflections from the sample 116 situated in the x-y plane that can be used for automated translation of the sample 116 in the x-y plane for raster-scan reflection imaging.

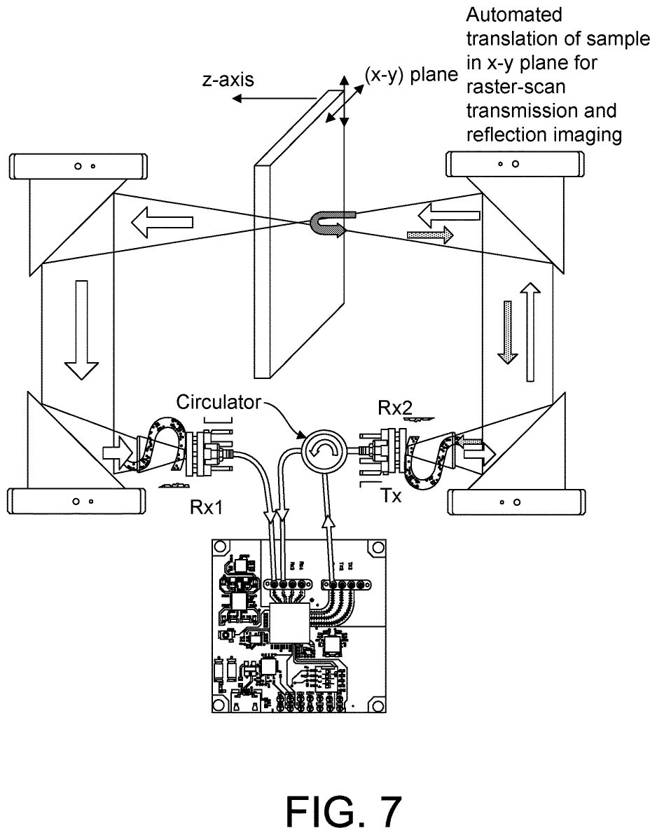

FIG. 7 is an illustration of one of the embodiments of a mmW VNA that can be used in a transmission and reflection imaging scenario. This scenario obtains not only transmissions through the sample 116, but also reflections from the sample 116 situated in the x-y plane that can be used for automated translation of the sample 116 in the x-y plane for raster-scan transmission and reflection imaging.

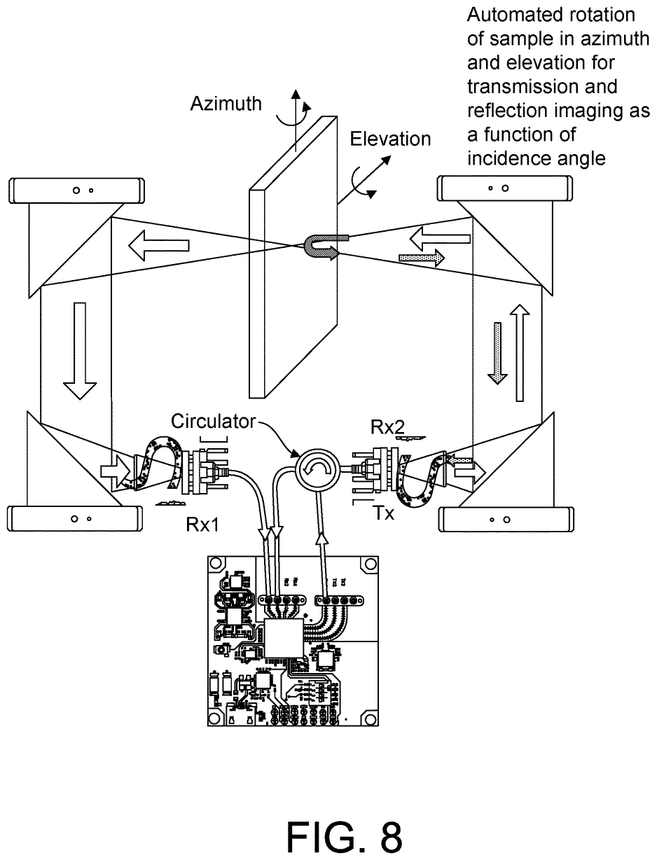

FIG. 8 is an illustration of one of the embodiments of a mmW VNA that can be used in an incident angle-dependent transmission and reflection imaging measurement scenario. Here, the sample 116 is rotated in the azimuth and/or elevation for transmission and reflection imaging as a function of incidence angle.

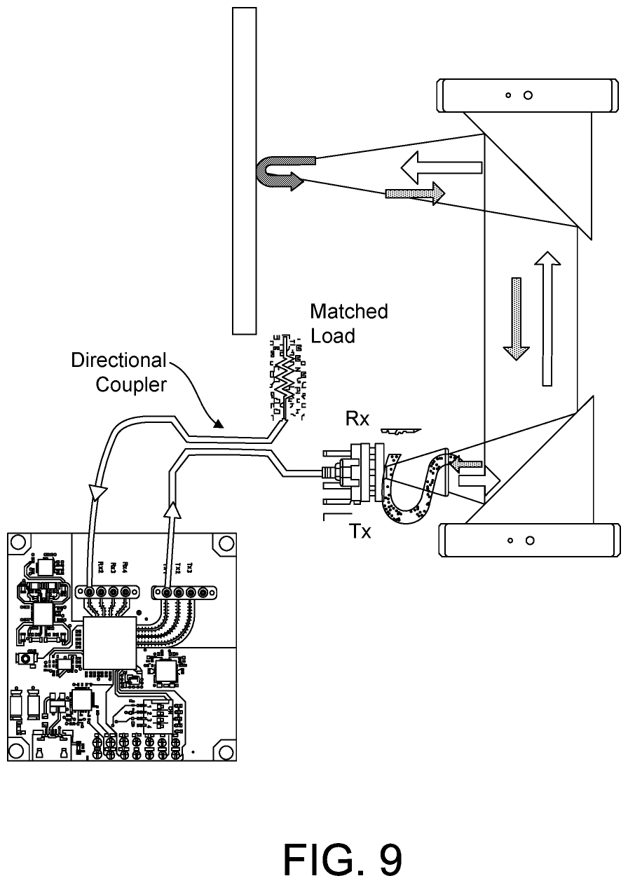

FIG. 9 is an illustration of one of the embodiments of a mmW VNA that can be used as a single-port (reflectometer) using an external directional coupler.

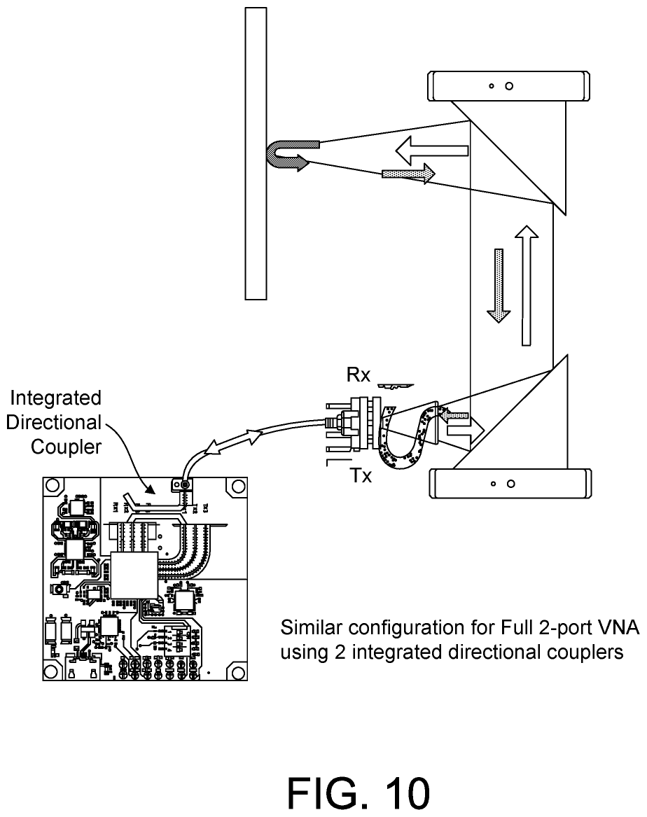

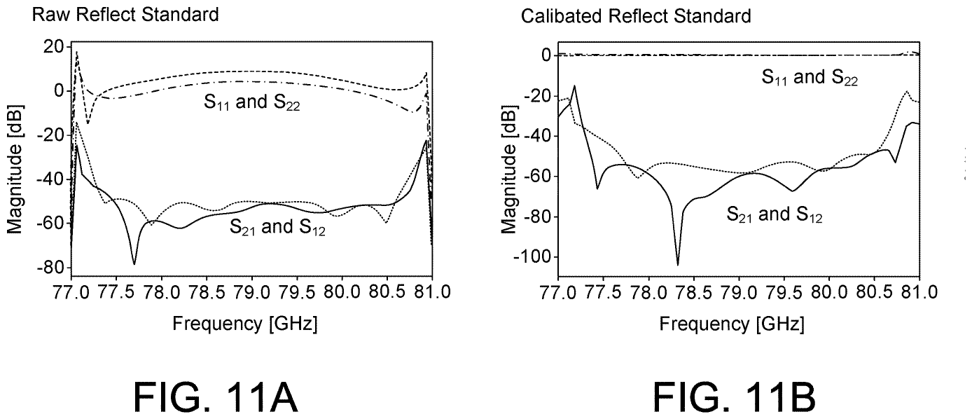

Similarly, FIG. 10 is an illustration of one of the embodiments of a mmW VNA that can be used as a single-port (reflectometer) using an integrated directional coupler, where the direction coupler is integrated into the mmW radar circuit board 102. A similar configuration provides for a full 2-port VNA using two integrated directional couplers. FIGS. 11A and 11B illustrate typical signals measured by the mmW VNA when a highly-reflective termination is applied to both ports, termed the Reflect Standard. FIG. 11A illustrates raw measured data and FIG. 11B illustrates measured data after calibration.

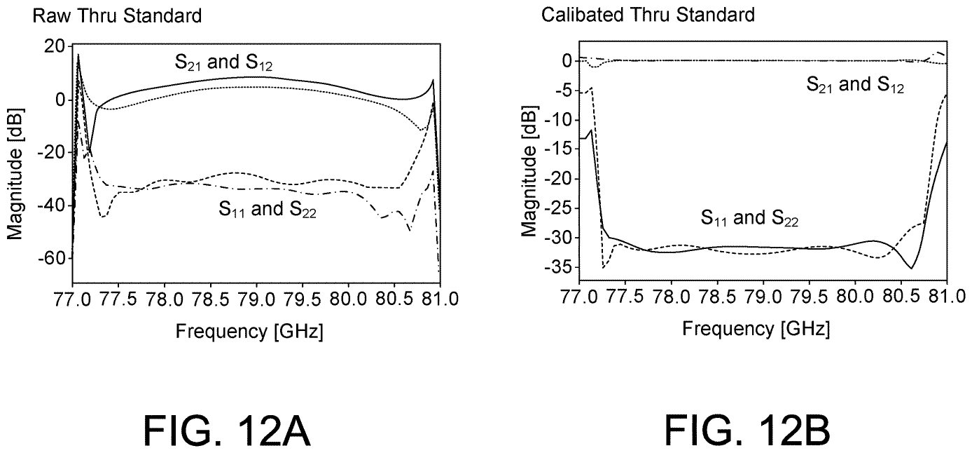

FIGS. 12A and 12 B illustrate typical signals measured by the mmW VNA when both ports are connected together, termed the Through Standard. FIG. 12A illustrates raw measured data and FIG. 12B illustrates measured data after calibration.

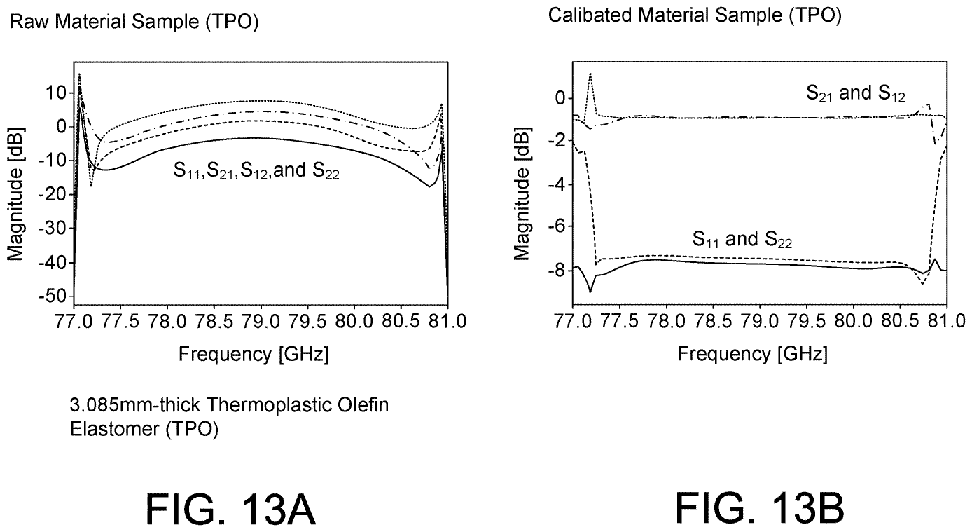

FIGS. 13A and 13B illustrate typical signals measured by the mmW VNA when a material sample (3.085 mm-thick Thermoplastic Elastomer-TPO) is placed between the two VNA ports. FIG. 13A illustrates raw measured data and FIG. 13B illustrates measured data after calibration.

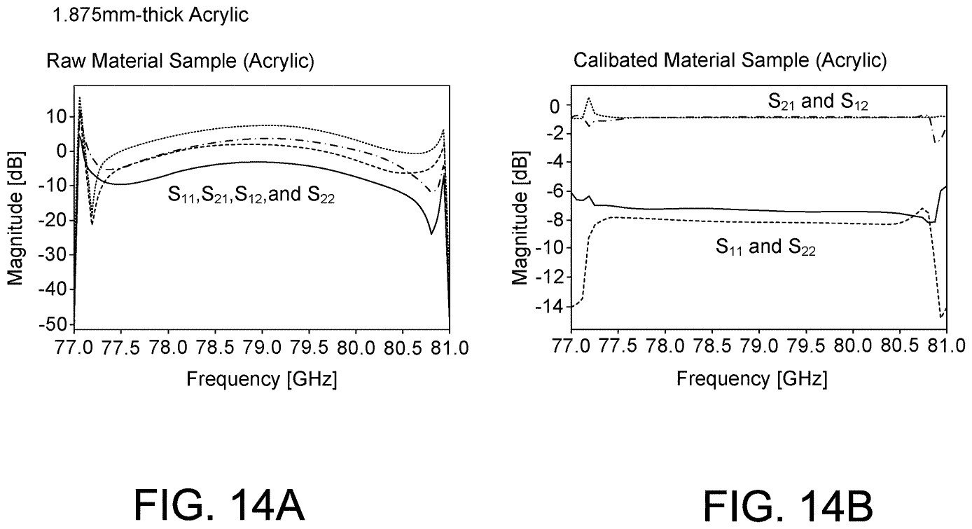

FIGS. 14A and 14B illustrate typical signals measured by the mmW VNA when a material sample (1.875 mm-thick Acrylic) is placed between the two VNA ports. FIG. 14A illustrates raw measured data and FIG. 14B illustrates measured data after calibration.

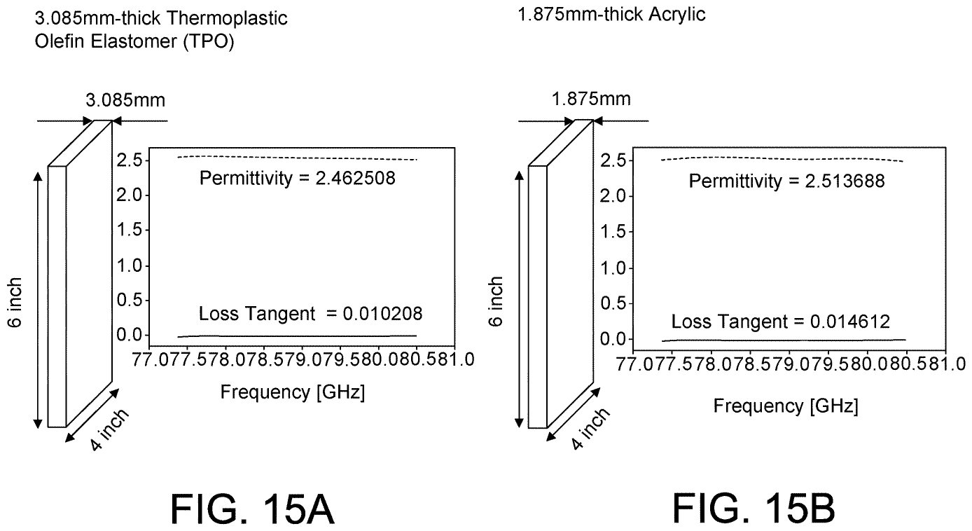

FIGS. 15A and 15B illustrate the extracted material properties (i.e. dielectric permittivity) of two representative material samples.

### Conclusion

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

Throughout this application, various publications are referenced. The disclosures of these publications in their entireties are hereby incorporated by reference into this application in order to more fully describe the state of the art to which the methods and systems pertain.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

1. A millimeter-wave (mmW) vector network analyzer (VNA) comprising:
a mmW radar circuit board modified to be connected to one or more devices, wherein the mmW radar circuit board comprises:
a plurality of board ports comprising a plurality of receive (Rx) channels and a plurality of (Tx) channels;
a mmW radar chip; and
a plurality of connectors,
wherein one or more of the plurality of Rx channels and one or more of the plurality of Tx channels are connected to the one or more devices using the plurality of connectors; and
one or more off-axis parabolic mirrors, wherein the one or more off-axis parabolic mirrors are used to transmit signals to, from and/or through a sample using the devices.

2. The mmW VNA of claim 1, wherein the plurality of board ports comprises seven board ports, comprising four Rx channels and three Tx channels.

3. The mmW VNA of claim 1, wherein the plurality of connectors replace an on-board antenna on the mmW radar circuit board.

4. The mmW VNA of claim 1, wherein leads are used to connect the Rx and Tx channels to the one or more devices.

5. The mmW VNA of claim 1, wherein the one or more devices comprise one or more Tx antenna, and/or one or more Rx antenna, and/or one or more combination Tx/Rx antenna.

6. The mmW VNA of claim 5, wherein the one or more devices further comprise one or more circulators.

7. The mmW VNA of claim 5, wherein the one or more devices further comprise one or more external directional couplers.

8. The mmW VNA of claim 5, wherein the one or more devices further comprise one or more integrated directional couplers.

9. The mmW VNA of claim 1, wherein a measurement scenario using the mmW VNA is considered with a target that is rotated in an azimuth and/or elevation direction for transmission and reflection imaging as a function of an incidence angle.

10. The mmW VNA of claim 1, wherein the mmW VNA is used to determine properties of the sample including multi-port, calibrated, S-parameter measurements, antenna characterization (including input impedance and antenna pattern), scattering cross section measurements, material characterization (permittivity and permeability), and imaging.
